(19) United States
(12) Patent Application Publication
(10) Pub. No.: US 2012/0180667 A1
(43) Pub. Date: Jul. 19, 2012

(54) Illuminating filter for particle controlled environments

(76) Inventors: Larry M. Ottesen, Brentwood, CA (US); James M. Harris, Livermore, CA (US)

(21) Appl. No.: 13/385,240

(22) Filed: Feb. 9, 2012

Related U.S. Application Data
(63) Continuation-in-part of application No. 12/313,531, filed on Nov. 21, 2008.
(60) Provisional application No. 61/009,893, filed on Jan. 3, 2008.

(51) Int. Cl. B01D 46/42; H05K 13/04

(52) U.S. Cl. 96/226; 55/385.1; 29/592.1

(57) ABSTRACT

An illuminating filter which provides both clean air and light to a particle controlled environment. The integration of filtration and lighting simplifies the design of cleanrooms, mini-environments, and clean zones. Space savings and cost savings are served by combining filtration and lighting into a single structure. Light emitters, such as LEDs or other solid state devices, may be used where low voltage or low current is desirable.

### CROSS-REFERENCE TO RELATED APPLICATIONS

This continuation-in-part application claims priority to U.S. Non-provisional application U.S. Ser. No. 12/313,531 (confirmation number 2278) filed Nov. 21, 2008 by Larry Ottesen and Jim Harris entitled, “ILLUMINATING FILTER FOR PARTICLE CONTROLLED ENVIRONMENTS”. This application also claims priority to U.S. Provisional Application 61/009,893 (confirmation number 6603) filed Jan. 3, 2008 by Larry Ottesen and Jim Harris entitled, “ILLUMINATING FILTER FOR PARTICLE CONTROLLED ENVIRONMENTS”.

### STATEMENT REGARDING FEDERALLY SPONSORED RESEARCH

Not Applicable

### REFERENCE TO A MICROFICHE APPENDIX

Not Applicable

### BACKGROUND OF THE INVENTION

1. Field of the Invention

This invention relates to filters which are used to remove particles or airborne molecular contaminants from clean environments. Clean environments include cleanrooms, mini-environments, or controlled work zones as defined by ISO Standard 14644. In particular, the instant invention addresses clean environments where lighting is utilized. The invention combines the filter and the lighting into a single filter unit. The invented filter may be installed into a ceiling grid structure, but a ceiling grid structure is not necessary.

2. Description of Related Art

Filters for removing particles from air (or other gases, such as nitrogen or argon) are a basic element of a clean work zone. Common filter categories include HEPA and ULPA, but this invention is independent of filter category.

Prior art filters include a filter media and a filter frame. The filter frame is usually metallic, and holds plus supports the filter media. Filter frames surround the filter media, and form the perimeter of the filter. Filter media is sealed to the frame with an adhesive seal.

The filter media (physically contained within a filter frame) traps particles which flow through it. Until the late 1990s, filter media was largely produced from borosilicate glass fibers. Modem filters for semiconductor application commonly use PTFE fibers.

Regardless of fiber type, the fibers form a barrier to particle penetration. Particles larger than 0.3 microns are mainly trapped by impaction, and particles smaller than 0.1 micron are mainly trapped by diffusion. Quality control testing of filters is normally performed at 0.10 to 0.15 micron.

Most particle controlled environments also require lighting. In an operating cleanroom, personnel are present. Sufficient lighting for vision is needed. In mini-environments, solid walls may partially block entry of ambient light. Internal lighting permits an outside operator to see inside.

Historically, filtration and lighting have been viewed as two separate issues. Designers of clean work zones specify the number of filters and the size of the filters, and place them into a grid. Designers also specify the number of lights, the placement of lights, and the intensity of lights. An example of the prior art is presented in U.S. Pat. No. 5,613,759, where a patented grid structure is totally independent from the type of filters or lights that are installed.

With a prior art grid system, filters and lights are typically designed at different times by different designers. Filters and lights are likely ordered from different vendors. This leads to at least three inefficiencies.

First, a separate grid position for prior art lighting is required. The grid space that holds a light normally differs in size from the grid space that holds a filter. Hence, lights don't fit into filter spaces, and filters don't fit into light spaces. If the lights are built into a mini-environment, the mini-environment frame has to be designed to include a lighting section. Then connectors to fasten the lights to the mini-environment frame must be added to the mini-environment. Because the filters and lights are separate components, filters do not include connectors or electrical wiring that are utilized by the lights.

Second, prior art electrical wiring for a grid system must be routed through a mini-environment frame to power the lights. For example, in U.S. Pat. No. 5,613,759, electrical wiring normally leads to tombstone connectors, and fluorescent lights are positioned onto the tombstone connectors. Of specific importance to this instant application, the prior art electrical wiring for lights does not penetrate or pass through any section of the filter. In the case of prior art fluorescent lights, 115 volt to 230 volt safety measures must be addressed.

Third is coordination. In general, the probability of error increases when lights and filters are handled separately. Consider a scenario wherein a purchasing paperwork error results in a mini-environment frame error, and the lighting section prevents the filter from fitting properly.

An analogous set of prior art problems exist for a cleanroom or clean zone installation. Filters or fan-filter modules are sized to fit a grid space (for vertical air flow). Then lighting is added to a separate grid space.

One distinguishing feature of the prior art grid is that lights are not disposed within the physical volume of the filter itself. By definition, the volume of the filter is product of the filter's length, width, and height. Lights are placed into a light grid space that is located beside or beneath the filter grid space.

A second distinguishing feature of the prior art is that the structural rails which form the prior art grid are different from the structural rails which comprise a filter frame. The reason is: the prior art grid rails do not connect directly to the filter media with an adhesive seal. Grid structural rails support the structural rails of the filter frame, and filter frame rails support the filter media with an adhesive seal. Prior art lights are placed beside or beneath the filter(s), not within the volume of the filter. The phrase “within the volume” means within the volume of space defined by the filter's height, width, and depth.

The prior art includes flow-through modules, which incorporate a filter plus one or two fluorescent lights. In this structure, the fluorescent lights are connected to a flow-through module frame, and the filter is attached to the same flow-through module frame. But the lights are not located within the boundaries of the filter frame. Normally, the lights are physically beneath the filter's volume. Further, electrical wires are not routed to or through the filter itself. Instead, electrical wires are routed outside the filter volume.

There is a need for an illuminating filter, where the lights and filters are combined into a single, inseparable structure. Further, the lights must be contained within the volume of the filter itself. This inventive concept obviates problems associated with excess costs, separate wiring, and over-lapping design errors.

### BRIEF SUMMARY OF THE INVENTION

Following is a condensed summary of the invention. By necessity, details are omitted in order to simply state the essence of the invention. Omitted details within this section should not be construed in a way that limits the scope of the invention.

This invention, an illuminating filter, is a filter with self-contained illumination segments. Illumination segments are positioned within the physical dimensions of the filter itself, not beside or beneath the filter.

Illumination segments are disposed within the physical dimensions of the filter, and the light emitters are disposed the physical dimensions of the illumination segments. Hence, the light emitters are also disposed within the physical dimensions of the filter. Illumination segments are typically implemented as a cross member of the filter frame that (1) supports the light emitters and (2) connects directly to the filter media with an adhesive seal. Because filter media is fragile, the light emitters do not connect directly to the filter media. Electrical wires to power the lights are routed through the illumination segment. Hence, some portion of the electrical wires is disposed within the physical dimensions of the filter itself.

An illuminating filter differs from the prior art filters and prior art ceiling grids because: (a) the illuminating filter performs both filtration and lighting, (2) the illuminating filter is made, used, or sold as a single structure, and (3) lights and illumination segments of an illuminating filter are disposed within the physical volume of the filter.

The physical dimension of an illuminating filter is defined as the volume of space located within the filter's height, width, and length. Height is the distance between the filter's inlet and outlet planes. The inlet plane of the filter includes that outside surface of the filter which faces toward the inlet air. The outlet plane of the filter includes that outside surface of the filter which faces toward the outlet air. Width and length correspond to the perimeter.

By combining the filter and illumination segment into one unit, problems associated with the prior art are resolved. Separate filter and light sections are no longer required. Wiring to the lights is simplified. Design and manufacturing errors are minimized.

In addition to minimizing negative factors inherent in the prior art, the illuminating filter also presents positive opportunities. For example, when low voltage solid state light emitters are incorporated, safety considerations are reduced and designers realize more flexibility. Also, solid state lights have a longer mean-time-between-failure than either fluorescent or incandescent lights. This translates into reduced maintenance.

Light emitters and illumination segments are always located within the physical dimensions of an illuminating filter. In one variation, the illumination segment (with light emitters) divides the filter media into two parts along the long filter dimension. In a second variation, the illumination segment divides the filter media into two parts along the short filter dimension. In a third variation, the illumination segment divides the filter media obliquely into two parts. In a fourth variation, the illumination is built into the perimeter of the filter frame.

Among many other application areas, this instant invention is applicable to mini-environments and cleanrooms. It also can be applied to diffusers, which receive and distribute clean air or gases (such as nitrogen or argon).

Industries within which illuminating filters have benefit include (but are not limited to) semiconductor, pharmaceutical, disk drive, flat panel display, solar energy, and MEMS.

Objects of this invention include:
(a) provide a filter or fan-filter module with light emitters disposed within the physical dimensions of an illuminating filter,
(b) simplify the process of installing both filters and lights,
(c) provide a one-piece solution for both filtration and lighting,
(d) utilize solid state lights where appropriate,
(e) allow the use of low voltage power.

### BRIEF DESCRIPTION OF THE SEVERAL VIEWS OF THE DRAWINGS

FIG. 1 shows a typical prior art filter. This filter does not incorporate an illumination segment. This filter could fit into a ceiling grid system such as the one described in U.S. Pat. No. 5,613,759. If lighting is also desired, a separate grid opening would be used.

FIG. 2 shows a prior art filter assembly that is constructed with a cross member included in the filter frame. This cross member is used for structural support only, and there is no adhesive joint between the cross member and the filter media. The filter assembly does not incorporate an illumination segment. No electrical wiring is present within the cross member. This filter could fit into a ceiling grid system such as the one described in U.S. Pat. No. 5,613,759. If lighting is also desired, a separate grid opening would be needed.

FIG. 3 diagrams a prior art fan-filter module. A fan-filter module contains blowers, housing, and a filter. Inlet and outlet planes of the filter are visualized.

FIG. 4 illustrates one embodiment of an illuminating filter. The invented illuminating filter provides both filtered air plus light. An illumination segment is disposed parallel to the short dimension of the illuminating filter, and is disposed within the physical boundaries of the filter. Note that the illumination segment is attached to the filter media with an adhesive seal. Electrical wiring is routed within the illumination segment to power the lights.

FIG. 5 illustrates one method of integrating light emitters into an illuminating filter. In this diagram, the illumination segment incorporates a structural cross member built into a filter frame. Inlet and outlet planes of the filter frame are visualized. Note that the cross member provides two functions: (1) it holds two cut sides of the filter media in place with adhesive seals connecting the cross member to the filter media, and (2) it provides within-the-filter electrical wiring to power the lights.

FIG. 6 diagrams an illuminating filter, wherein the illumination segment is disposed parallel to the long dimension of the illuminating filter.

FIG. 7 shows an illuminating filter, wherein the illumination segment is not disposed parallel to either the long dimension or the short dimension of the illuminating filter.

FIG. 8 shows an illuminating filter, wherein the illumination segment is implemented as the perimeter of the filter frame.

FIG. 9 illustrates an illuminating filter, wherein the light emitter is one continuous light emitting structure as opposed to an ensemble of discrete light emitters.

FIG. 10 shows an illuminating filter that has been incorporated into a fan-filter module.

FIG. 11 illustrates an illuminating filter incorporated into a fan-filter module. The fan-filter module is further incorporated into a mini-environment or clean zone.

### DETAILED DESCRIPTION OF THE INVENTION

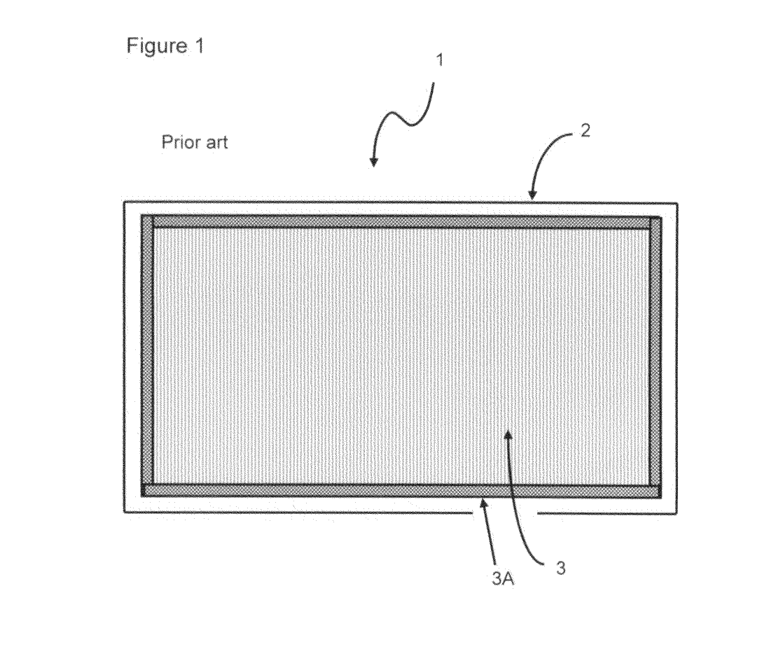

FIG. 1 shows a prior art air (or gas) filter 1. Filters are used in clean zones, which are categorized into nine classes by ISO Standard 14644. This is a planar view, and the view is perpendicular to the direction of air flow. The filter media 3 removes particles from the air as air passes through the filter media 3. Although filters 1 are discussed in terms of air filtration, filters 1 are also used to filter other gases, such as nitrogen or argon.

Filter media 3 is fragile, and must be attached to a filter frame 2. This attachment normally utilizes an adhesive seal 3A. Without an adhesive seal 3A, dirty air would bypass the filter media, and the filter would be ineffective. The filter frame 2 provides structural rigidity and support for the filter media 3. When a filter 1 is manually handled, it is picked up with the filter frame 2. Filter frames are typically constructed from passivated metal. For example, aluminum passivated by a layer of aluminum oxide is commonly chosen for construction.

Filter media 3 may include borosilicate glass fibers, PTFE (polytetrafluoroethylene), or other materials. Filtration efficiencies are chosen to match the application. Low efficiency filters 1 are used in non-critical clean zones. HEPA efficiency particulate air) or ULPA (ultra low particulate air) filters 1 are currently used in more critical applications, such as semiconductor, disk drive, pharmaceutical, flat panel display, solar panel, and MEMS production.

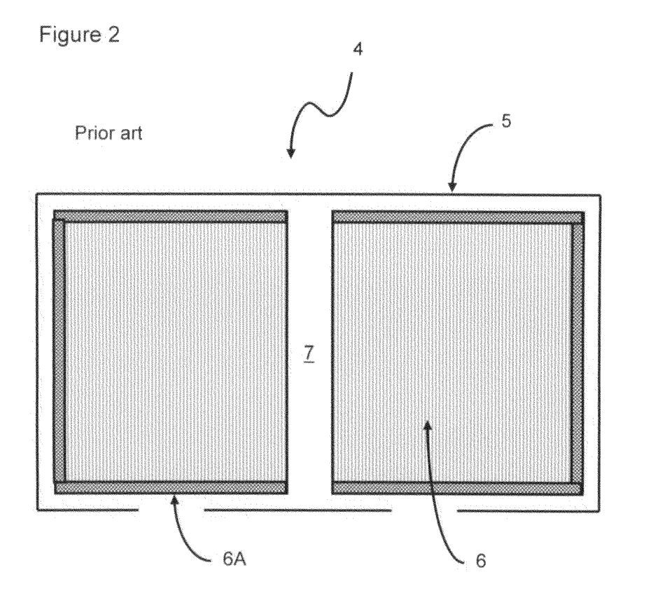

FIG. 2 shows another prior art filter 4. Here the filter frame 5 possesses a cross member 7 which does not divide the filter media 6 into two pieces. In this configuration, the cross member 7 is present only for structural support of the frame. No illumination segment is included. No lights are present, and no electrical wiring is routed through the cross member 7. An adhesive seal 6A joins the filter frame 5 to the filter media 6. But the filter media 6 is not joined to the cross member 7 with an adhesive seal.

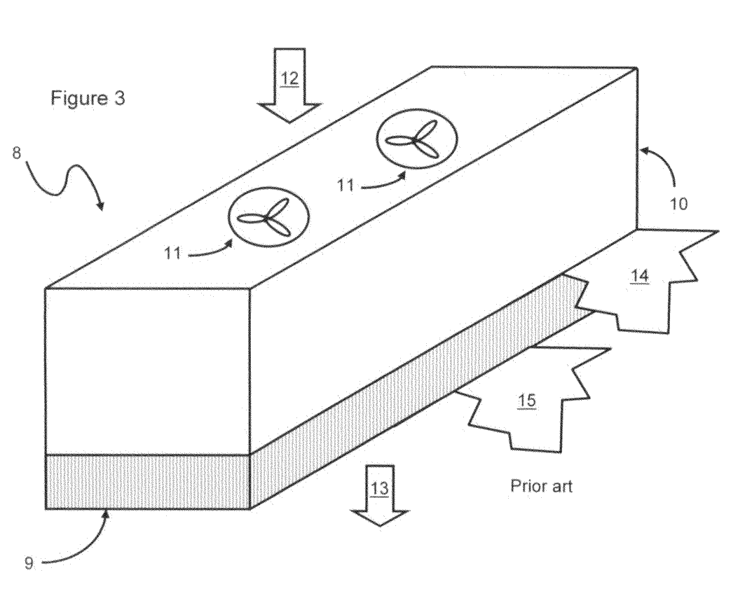

FIG. 3 shows a fan-filter module 8, which is also a prior art commercial filtration product. The fan-filter module 8 uses blowers 11 to draw air (or gas) from the environment and build a positive air pressure inside a housing 10. The positive pressure causes air to flow through the filter 9. The filter 9 has an inlet plane 14 (top outside surface of the filter 9 and an outlet plane 15 (bottom outside surface of the filter 9). As shown, inlet air 12 flows into the housing 10, and outlet air 13 flows outward from the housing 10 through the filter 9. The outlet air 13 is directed into a clean zone.

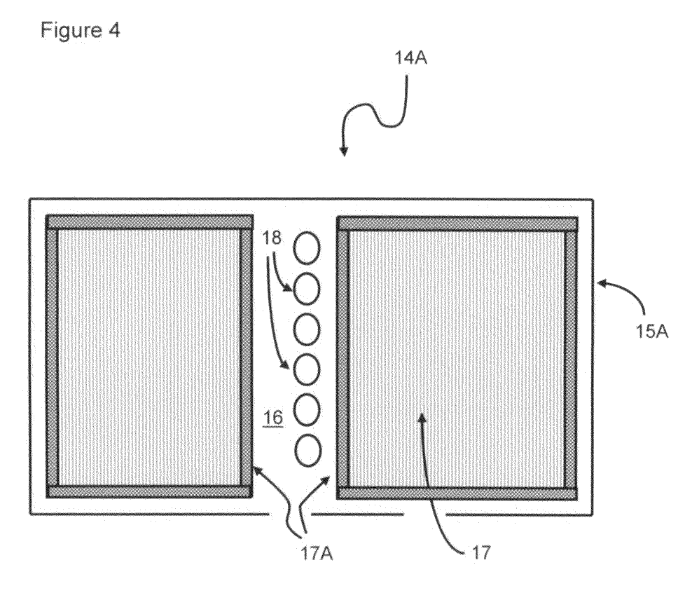

FIG. 4 shows one embodiment of an illuminating filter 14A. In this embodiment, the filter frame 15A possesses an illumination segment 16 that divides the filter media 17 into two portions. An adhesive seal 17A exists at both interfaces between the illumination segment 16 and filter media 17. The illumination segment 16 includes a series of light emitters 18. Light from the illumination segment 16 is directed in the same direction as the clean air flow. The two portions of filter media 17 can take a variety of shapes. For example, the two portions may be equal in size or unequal. The geometrical shapes may be the same or different since the illumination segment 16 may span the filter frame 15A in multiple ways. The illumination segment 16 may be parallel, perpendicular, or oblique to either the pleat end or cut end of the filter media 17. However, the interface between the illumination segment 16 and the filter media 17 must be joined with an adhesive seal 17A.

Note that the illumination segment 16 has three necessary features: (1) it contains the light emitters 18 within the filter's 14A physical volume, (2) it attaches directly to the filter media 17 with an adhesive seal 17A, and (3) it contains electrical wiring (not shown) to power the lights. This is structurally and functionally different from placing lights into a ceiling grid. Specifically, (a) a ceiling grid disposes filters and lights in different grid locations; (b) structural grid bars do not connect to filter media with an adhesive seal; and (c) electrical wiring associated with grid lights does not pass through an illumination segment.

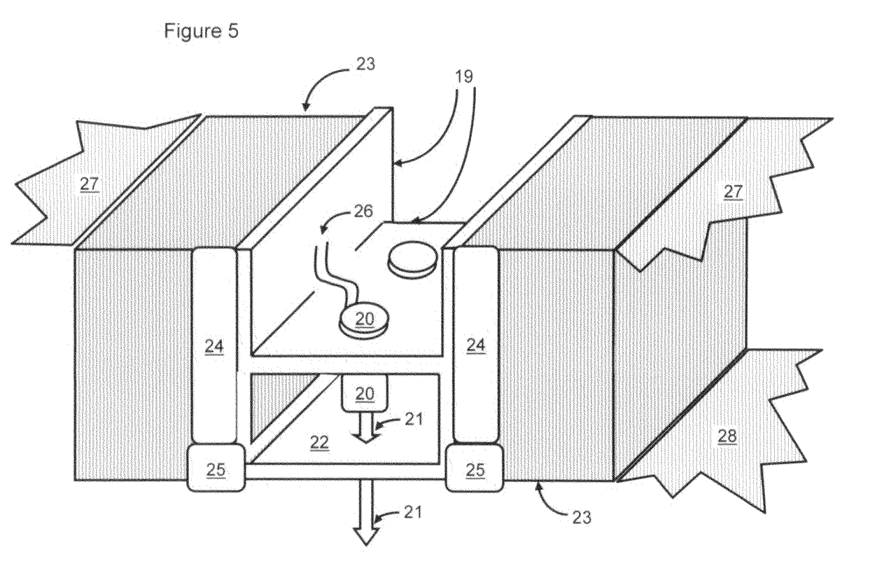

FIG. 5 shows one example of connecting light emitters 20 to an illumination segment 19, which divides the filter media 23 into two sections and joins to those two sections with adhesive seals 24. In this example, the light emitters 20 are contained within the illumination segment 19 and light 21 passes through an opening in the illumination segment 19. Electrical wires 26 are contained within a hollow channel of the illumination segment 19, and supply power to the input side of the light emitters 20. Light 21 from the light emitters 20 pass through a light cover 22. The light cover 22 protects the light emitters 20 from handling damage. Note that the light emitters 20 are located between the filter's inlet plane 27 and the filter's outlet plane 28. No portion of the light emitters extends outward beyond the filter's physical volume. Light emitter spacing along the illumination segment 19 is variable, depending on application. For example, light emitters 20 could be 3 inches apart or 0.5 inches apart. Or, light emitters 20 could be disposed in a quasi-continuous pattern.

In addition, the light cover 22 can serve to filter the light 21. Light filtration has value in photolithography equipment and other processes where photochemical reactions can be detrimental. For example, filtering the light between 300-550 nm shifts the transmitted light distribution toward yellow and red. Actual removal percentages and spectral ranges are determined on a case-by-case basis to fit the application.

When an illumination segment 19 divides filter media 23 into pieces, adhesive seals 24 at each interface are needed. The same adhesive normally used for attaching filter media to a filter frame may be used. Adhesive seals 24 may occur on the cut end or the pleat end of the filter media 23, depending on orientation.

The light cover 22 is also sealed to the illumination segment 19 with cover sealing 25. The cover sealing 25 again comprises an adhesive.

The light cover 22 may be used in a pharmaceutical facility or a hospital. So, the light cover 22 must be compatible with bactericides, fungicides, alcohols, and oxidizing agents. Perchlorates are oxidizing agents that may be present in bactericides and fungicides.

Attachment of the light emitters 20 to the illumination segment 19 may utilize a variety of fastening mechanisms. For example, quarter-turn screws, flanges, threading, gluing, or tapered holes may be used. This fastener list is not intended to be complete, and a plethora of commercially available fasteners are applicable. For ease of replacement or service, light emitters 20 may be attached to a retainer that detachably fits onto the illumination segment 19, and remain within the inventive concept.

Spacing of the light emitters 20 is variable. For high intensity lighting, light emitters 20 may be positioned such that the less than ½ inch separates adjacent surfaces between neighboring light emitters 20. For medium intensity light, light emitters 20 may be positioned such that ½ to 3 inches separate adjacent surfaces between neighboring light emitters 20. For low intensity light, light emitters 20 may be positioned with more than 3 inches between neighboring light emitters 20.

A useful known category of light emitters 20 are devices that convert either current or voltage to light. Some of these are solid state devices. Within the solid state category are LEDs (light emitting diodes).

Solid state light emitters 20 can operate at low voltages. Electrical wires 26 for typical LEDs provide 12-24 volts. Lower voltage solid state devices may operate between 1.5 and 12 volts. Higher voltage solid state devices may operate between 24 and 48 volts.

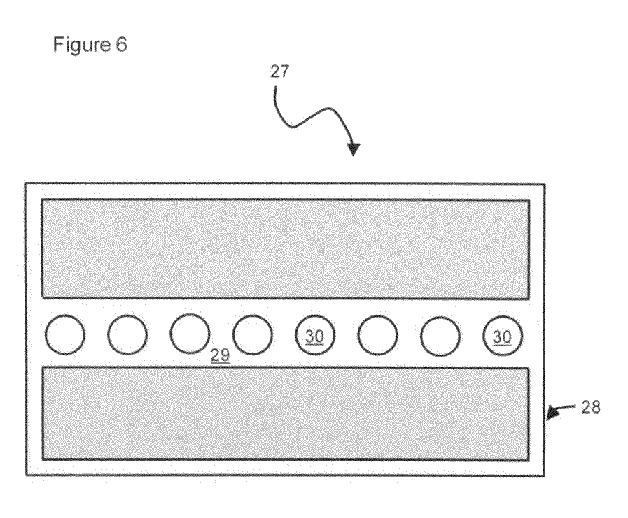

FIG. 6 shows an alternate embodiment of an illuminating filter 27. In this embodiment, the illumination segment 29 is disposed parallel to the long dimension of the filter frame 28. Hence, the light emitters 30 form a line that is aligned with the long dimension of the filter frame 28. Adhesive seals are not shown, but they are necessarily present. Electrical wiring inside the illumination segment 29 is not shown.

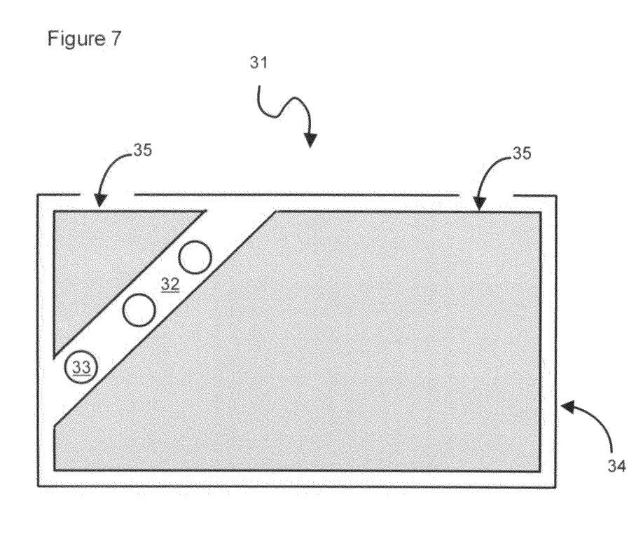

FIG. 7 shows another embodiment of an illuminating filter 31. Note that the illumination segment 32 is not parallel to either the length or width of the filter frame 34. Again, the light emitters 33 are built into the illumination segment 32. This arrangement divides the filter media 35 into pieces with different shapes. Adhesive seals are not shown, but they are necessarily present. Electrical wiring inside the illumination. segment 32 is not shown.

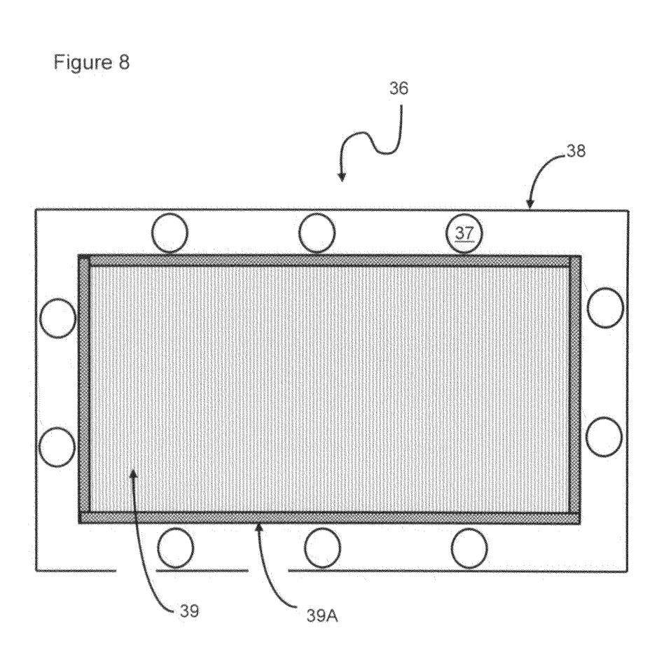

FIG. 8 shows another embodiment of an illuminating filter 36. In this embodiment, the light emitters 37 are disposed within the filter frame 38. That is, the illumination segment is implemented using the filter frame 38 rather than using a separate cross member. The filter media 39 is undivided, and the filter frame 38 contains electrical wiring to the light emitters 37. The filter frame 38 joins to the filter media 39 on four sides with an adhesive seal 39A.

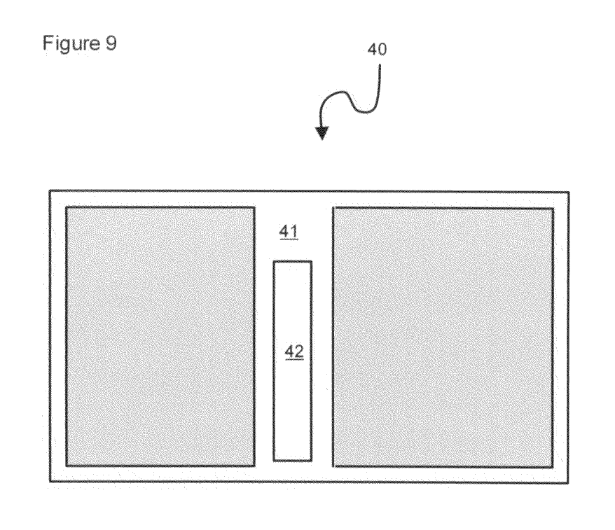

FIG. 9 shows another embodiment of an illuminating filter 40. In this case, the illumination segment 41 contains a continuous light emitter 42 as opposed to a series of discrete solid state devices. Any given area of the light emitter 42 produces substantially the same light output.

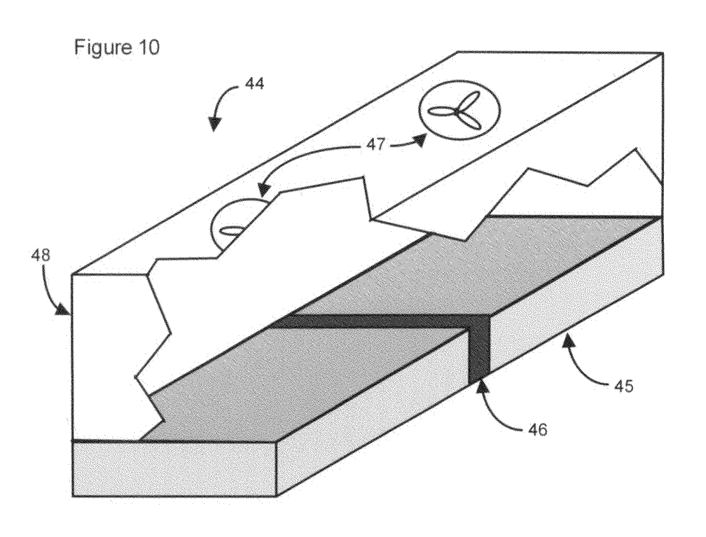

FIG. 10 shows an illuminating filter 45 that has been included into a fan-filter module 44. In this configuration, the blowers 47 pull air from the surrounding environment into a housing 48. Pressure builds up inside the housing 48, and drives air through the illuminating filter 45. In this example, the illumination segment 46 (electrical wiring and adhesive seals are not shown) is parallel to the short dimension of the illuminating filter 45.

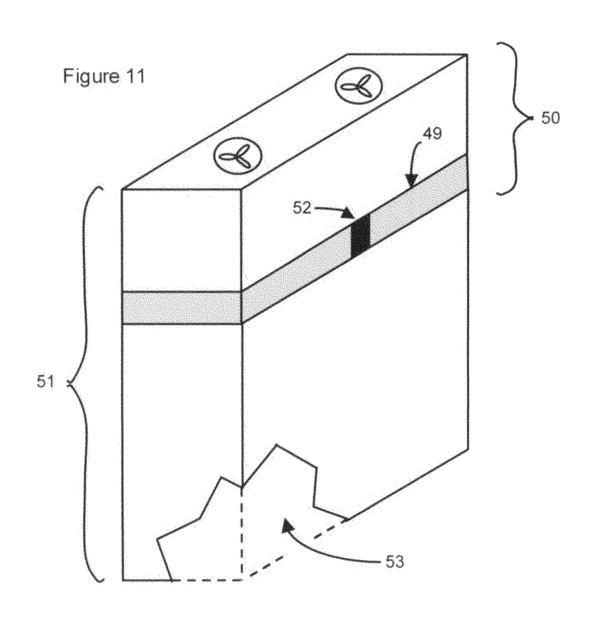

FIG. 11 shows an illuminating filter 49 included into a fan-filter module 50, and the fan-filter module 50 is further included into a mini-environment 51. As shown, the illumination segment 52 is parallel to the short dimension of the illuminating filter 49. Both light and filtered air are directed into the clean zone 53.

The above embodiments are examples of the inventive concept. These examples are designed to clarify the inventive concept, but not to limit the inventive concept. Many variations are possible which remain within the invention scope, and obvious to those of ordinary skill within the lighting and filtration fields.

Light emitting devices are becoming more efficient with time. The inventive concept is not limited to types of light emitters that are available today or to types of filter media that are available today.

Any of the filters or fan-filter modules shown in FIG. 1, 2, 3, 4, 5, 6, 7, 8, 9, or 10 could fit onto a ceiling grid. However, there are, uses which do not require a ceiling grid.

The invention claimed is:

1. An illuminating filter comprising:
one or more sections of filter media,
which remove particles from a gas flowing through said filter media;
a filter frame,
which has an inlet plane through which unfiltered air or gas enters,
which has an outlet plane through which filtered air is delivered,
which supports said filter media, and
which joins to said filter media with adhesive seals;
one or more illumination segments
which are disposed within the volume of said illuminating filter,
which include light emitters,
wherein said light emitters are also disposed within said volume of said illuminating filter,
wherein no portion of said light emitters extends outward beyond said inlet plane or said outlet plane of said illuminating filter, and
which direct light to a filtered work space;
electrical wiring to power said light emitters
which is partly disposed within said illumination segment; and
adhesive seals for connecting said one or more illumination segments to said filter media.

2. Claim 1 where said filter media, said filter frame, and said illumination segments are manufactured and sold as a single structure.

3. Claim 1 where said gas comprises any one selected from a group consisting of air, nitrogen, and argon.

4. Claim 1 where said filter frame surrounds said one or more sections of filter media.

5. Claim 1 where said adhesive seal partly comprises silicones.

6. Claim 1 where said filter frame surrounds said illumination segment, and said illumination segment divides said filter media into two or more separated areas.

7. Claim 6 where said illumination segment is structurally connected to any two sides of said filter frame.

8. Claim 1 where said light emitters comprise devices that convert voltage or current to light.

9. Claim 1 where said light emitters are attached to said illumination segment via quarter turn screws, snap-on retainers, flanges, threading, gluing, tapered holes, non-silicone adhesive, silicone adhesive, hot melt glue, rigid wiring harness, or self adhesive retainer.

10. Claim 1 where said illumination segment further comprises a light cover.

11. Claim 10 where said light cover includes opaque areas and transmitting areas, and said transmitting areas pass a greater percentage of light.

12. Claim 10 where said light cover is chemically compatible with any one selected from a group consisting of bactericides, fungicides, isopropyl alcohol, perchlorates and oxidizing agents.

13. Claim 1 where said light emitters comprise solid state light emitting diodes.

14. Claim 1 where a light cover is disposed over said illumination segment, and said light cover is transparent at those locations through which light is intentionally directed.

15. Claim 1 where said volume of said illuminating filter means the volume of space within the filter's length, width, and height.

16. A method of building an integrated illuminating filter comprising:
connecting two or more pieces of filter media to a filter frame and to an illumination segment,
wherein said illumination segment is fully contained within the physical volume of said illuminating filter;
attaching light emitters to said illumination segment,
wherein said light emitters are also fully contained within said volume of said illuminating filter;
sealing said filter media to said illumination segment and to said filter frame with an adhesive seal; and
routing electrical wiring through said illumination segment to power said light emitters.

17. The method of claim 16 further installing said illuminating filter onto a ceiling grid.

18. The method of claim 17 wherein said ceiling grid is described in U.S. Pat. No. 5,613,759.

19. The method of claim 16 further installing a light cover.
